(19) United States
(12) Patent Application Publication
(10) Pub. No.: US 2022/0221635 A1
(43) Pub. Date: Jul. 14, 2022

(54) INFRARED FILTER AND THERMAL INFRARED SENSING DEVICE INCLUDING THE SAME

(71) Applicant: Godsmith Microelectronics Inc., Chutung Township (TW)

(72) Inventor: Jin-Shown SHIE, Baoshan Township (TW)

(21) Appl. No.: 17/646,906

(22) Filed: Jan. 4, 2022

(30) Foreign Application Priority Data
Jan. 11, 2021 (TW) 110100929

(51) Int. Cl. G02B 5/20; H01L 27/146

(52) U.S. Cl. CPC G02B 5/208; H01L 27/14649; H01L 27/14625; H01L 27/14618

(57) ABSTRACT

An infrared (IR) filter includes a silicon substrate and a metallic reticulated structure that is disposed on the silicon substrate and that is formed with a plurality of holes for transmitting IR light. Also disclosed is a thermal IR sensing device including the IR filter. The thermal IR sensing device includes a housing defining a vacuum chamber, a thermal IR image detector disposed within the vacuum chamber, and the IR filter coupled to the housing in position away from the thermal IR image detector with the metallic reticulated structure facing the thermal IR image detector. The IR filter allows an incident IR light to transmit therethrough so as to be detected by the thermal IR image detector.

### CROSS-REFERENCE TO RELATED APPLICATION

This application claims priority of Taiwanese Invention Patent Application No. 110100929, filed on Jan. 11, 2021.

### FIELD

The disclosure relates to a light filter, and more particularly to an infrared filter and a thermal infrared sensing device including the same.

### BACKGROUND

FIG. 1 illustrates a conventional thermal infrared sensing device 9, such as a thermographic camera. The conventional thermal infrared sensing device 9, which is sensitive to an infrared light (L) having a wavelength ranging from 8 μm to 14 μm, includes a housing 91 defining a vacuum chamber 911, a thermal infrared image detector 92 disposed within the vacuum chamber 911, and a filter 93 that is mounted to the housing 91 and that is arranged in front of the thermal infrared image detector 92 in an incident direction of the infrared light (L). The vacuum chamber 911 is used for preventing heat loss from the thermal infrared image detector 92 when an atmospheric pressure is higher than a pressure in the vacuum chamber 911. The filter 93 might be a germanium (Ge) substrate or a silicon (Si) substrate.

Referring to FIG. 2, the Ge substrate has a relatively high transmittance to the infrared light (L) that has a wavelength ranging from 3 μm to 14 μm. Hence, the Ge substrate is suitable to serve as the filter 93. Nevertheless, the Ge substrate is too expensive to be commercialized, and is brittle, hence, is unsuitable for mass production. Therefore, the Si substrate is more often used to serve as the filter 93 due to cost consideration. However, the Si substrate has a relatively low transmittance to the infrared light (L) having a wavelength ranging from 8 μm to 14 μm.

In order to improve the low transmittance of the Si substrate to the infrared light (L) having a wavelength ranging from 8 μm to 14 μm, reduction of a thickness of the Si substrate is proposed. FIG. 3 illustrates the spectral transmittance of Si substrates that have different thickness and that are formed by different methods. The curves A and C represent the spectral transmittance of the Si substrates formed by a floating zone method and having a thickness of 5 mm and 20 mm, respectively. Curves B and D represent the spectral transmittance of the Si substrates formed by a Czochralski method and having a thickness of 5 mm and 20 mm, respectively. It can be seen that the thinner the Si substrate is, the higher the transmittance to the infrared light (L) having the wavelength of 8 μm to 14 μm is. Nevertheless, the thinner Si substrate tends to be deformed or bended, resulting in breaking of the Si substrate due to the atmospheric pressure being higher than the pressure in the vacuum chamber 911.

### SUMMARY

Therefore, an object of the disclosure is to provide an infrared filter that can alleviate or eliminate at least one of the drawbacks of the prior art.

According to an aspect of the disclosure, an infrared filter includes a silicon substrate and a metallic reticulated structure that is disposed on the silicon substrate and that is formed with a plurality of holes for transmitting an infrared light.

According to another aspect of the disclosure, a thermal infrared sensing device includes a housing defining a vacuum chamber, a thermal infrared image detector disposed within the vacuum chamber, and the abovementioned infrared filter coupled to the housing in position away from the thermal infrared image detector with the metallic reticulated structure facing the thermal infrared image detector. The infrared filter allows an incident infrared light to transmit therethrough so as to be detected by the thermal infrared image detector.

### BRIEF DESCRIPTION OF THE DRAWINGS

Other features and advantages of the disclosure will become apparent in the following detailed description of the embodiments with reference to the accompanying drawings, of which:

FIG. 1 is a cross-sectional view of a conventional thermal infrared sensing device;

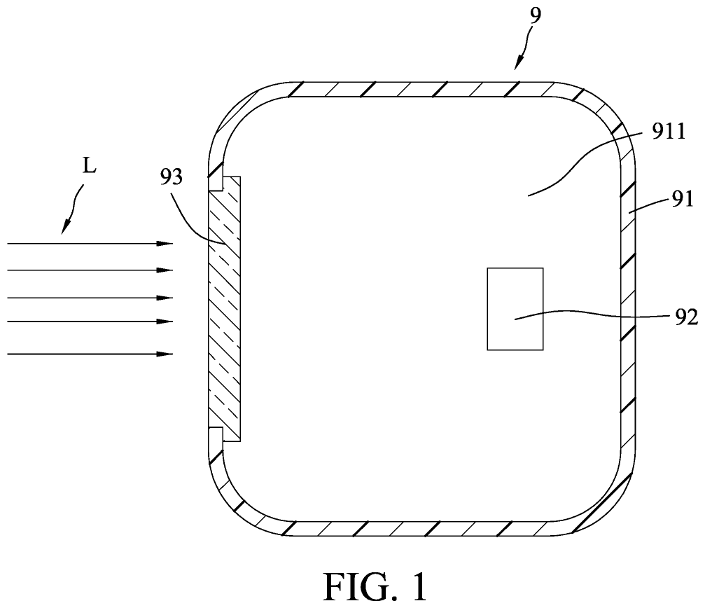

FIG. 2 is a graph illustrating transmittance curves of a germanium substrate and a silicon substrate at various wavelengths, respectively;

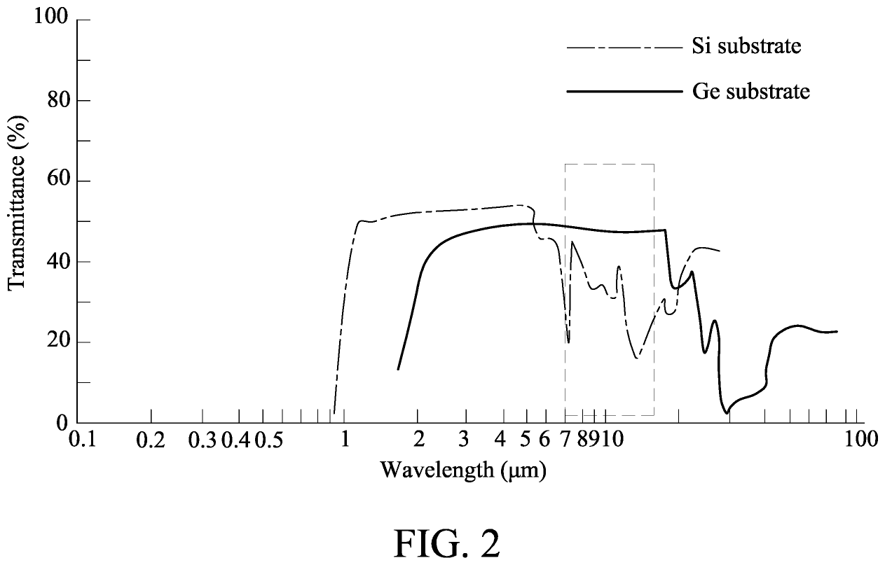

FIG. 3 is a graph respectively illustrating transmittance curves of silicon substrates each having different thickness and being formed by different methods at various wavelengths;

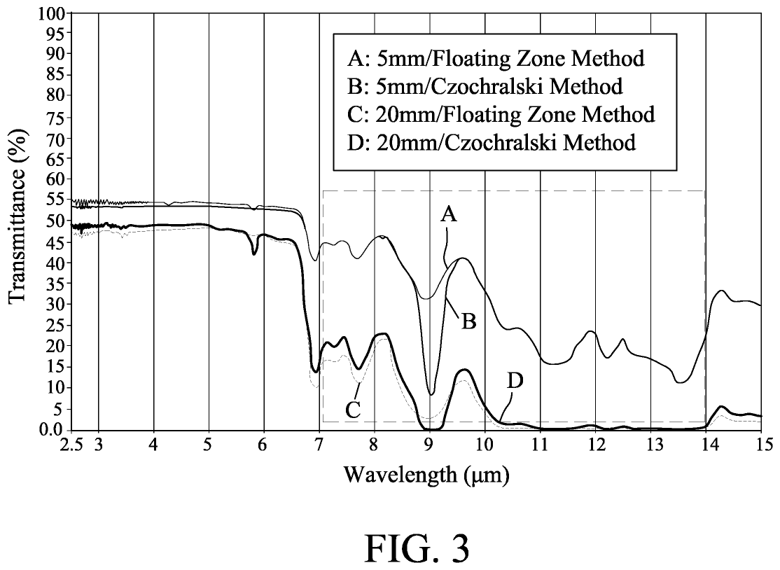

FIG. 4 is a perspective view illustrating an embodiment of an infrared filter of the disclosure;

FIG. 5 is a cross-sectional view of an embodiment of a thermal infrared sensing device including the infrared filter of the disclosure; and

FIG. 6 is a perspective cutaway view of the thermal infrared sensing device of FIG. 5.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

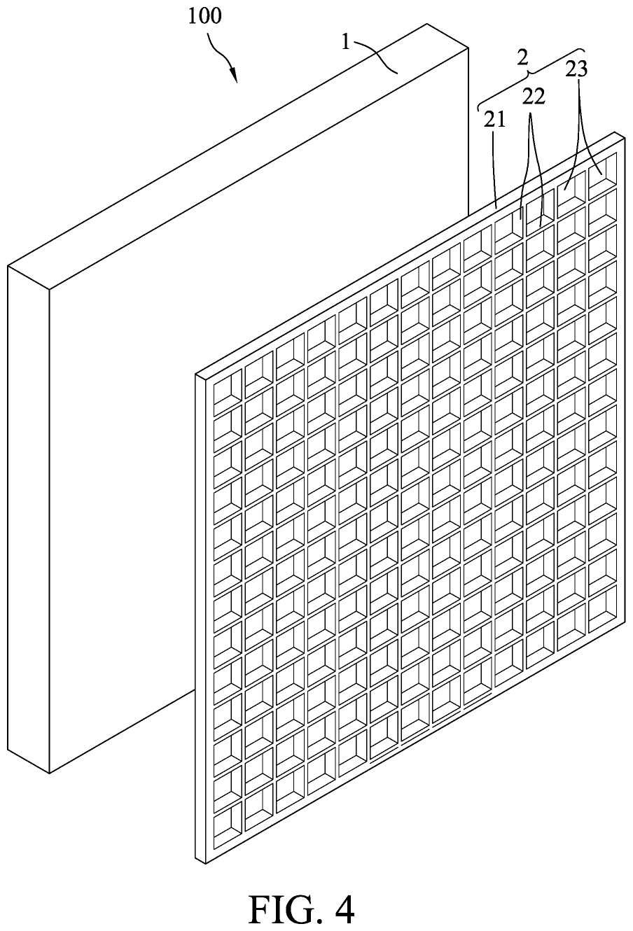

Referring to FIG. 4, an embodiment of an infrared filter 100 of the disclosure includes a silicon substrate 1, and a metallic reticulated structure 2 that is disposed on the silicon substrate 1. The metallic reticulated structure 2 includes a metallic frame 21, and a plurality of metallic wires 22 that are connected to the metallic frame 21 and that are interlaced with each other to form a plurality of holes 23 for transmitting an infrared light (L).

The silicon substrate 1 has a thickness of less than 0.5 mm, and may be fabricated by a floating zone method or a Czochralski method. In this embodiment, the silicon substrate 1 is fabricated by the Czochralski method for reducing cost.

The metallic reticulated structure 2 is made of a metal or a metallic alloy. In this embodiment, the metallic reticulated structure 2 is made of titanium.

The metallic frame 21 is disposed on a boundary of a surface of the silicon substrate 1. The metallic frame 21 has a shape conforming with that of the silicon substrate 1.

Each of the holes 23 has a dimension selected from a square, a rectangle, a rhombus, a circle, and a hexagon, but is not limited thereto, as long as the holes 23 allow the infrared light (L) to pass therethrough. Hence, an arrangement of the metallic wires 22 is varied to comply with the dimension of the holes 23. In some embodiments, the metallic wires 22 are connected to and criss-cross between any two opposite sides of the metallic frame 21, such that the holes 23 have a dimension of a square or a rectangular. In this embodiment, a dimension of each of the holes 23 is square, and the holes has a length of 50 μm and a width of 50 μm, but is not limited thereto.

In this embodiment, a mechanical strength of the infrared filter 100 is enhanced by disposing the metallic reticulated structure 2 on the surface of the silicon substrate 1. Thereby, a deformation or bending of the silicon substrate 1 is reduced when an external force is applied to another surface of the silicon substrate 1 opposite to the metallic reticulated structure 2. In order to verify the improvement in the mechanical strength of the infrared filter 100 of the disclosure, a deformation and a corresponding stress of each of a comparative example of a conventional infrared filter and Examples 1 to 5 of the infrared filter 100 of the disclosure are listed in Table 1. The values of deformation and the corresponding stress are obtained using an ANSYS simulation software.

The infrared filter 100 of Example 1 includes the silicon substrate 1 and the metallic reticulated structure 2 disposed thereon. The metallic reticulated structure 2 is made of titanium, has a thickness of 1 μm, and is formed with the holes 23. Each of the holes 23 has a square dimension with a length of 50 μm and a width of 50 μm. Examples 2 to 5 of the infrared filter 100 are similar to that of Example 1 except that the metallic reticulated structures 2 of Examples 2 to 5 of the infrared filter 100 have thickness of 2 μm, 4 μm, 8 μm, and 16 μm, respectively. The conventional infrared filter of the comparative example is structurally similar to the infrared filter of Example 1 except that the conventional infrared filter does not include the metallic reticulated structure 2.

TABLE 1

| | | | | | | | | Comparative |
|---|---|---|---|---|---|---|---|---|
| | | | | | | | | example |
| | | | Examples | | | | | 1 |
| | | | 1 | 2 | 3 | 4 | 5 | Without |
| Metallic | Material | | Ti | Ti | Ti | Ti | Ti | metallic |
| reticulated | Thickness (μm) | | 1 | 2 | 4 | 8 | 16 | reticulated |
| structure | Width/length (μm) | | 50/50 | 50/50 | 50/50 | 50/50 | 50/50 | structure |
| Pressure | 0.5 | Deformation | −0.83 | −0.79 | −0.71 | −0.58 | −0.41 | −0.85 |
| (atm) | | (μm) | | | | | | |
| | | Stress (MPa) | 26.6 | 25.1 | 23.5 | 19.8 | 14.2 | 26.4 |
| | 1 | Deformation | −1.66 | −1.57 | −1.41 | −1.16 | −0.82 | −1.71 |
| | | (μm) | | | | | | |
| | | Stress (MPa) | 53.2 | 50.2 | 47 | 39.7 | 28.4 | 52.8 |
| | 2 | Deformation | −3.32 | −3.14 | −2.82 | −2.32 | −1.65 | −3.42 |
| | | (μm) | | | | | | |
| | | Stress (MPa) | 106.3 | 100.4 | 94.1 | 79.3 | 56.9 | 105.5 |
| | 4 | Deformation | −6.73 | −6.37 | −5.72 | −4.71 | −3.34 | −6.93 |
| | | (μm) | | | | | | |
| | | Stress (MPa) | 215.5 | 203.4 | 190.6 | 160.8 | 115.2 | 213.8 |
| | 5 | Deformation | −8.41 | −7.96 | −7.15 | −5.89 | −4.18 | −8.66 |
| | | (μm) | | | | | | |
| | | Stress (MPa) | 269.4 | 254.2 | 238.3 | 200.9 | 144 | 267.3 |
| | 6 | Deformation | −10.1 | −9.56 | −8.58 | −7.07 | −5.01 | −10.39 |
| | | (μm) | | | | | | |
| | | Stress (MPa) | 323.2 | 305.1 | 286 | 241.1 | 172.8 | 320.7 |
| | 8 | Deformation | −13.5 | −12.7 | −11.4 | −9.42 | −6.68 | −13.85 |
| | | (μm) | | | | | | |
| | | Stress (MPa) | 423.1 | 406.8 | 381.3 | 321.5 | 230.4 | 427.6 |
| | 10 | Deformation | −16.8 | −15.9 | −14.3 | −11.8 | −8.35 | −17.31 |
| | | (μm) | | | | | | |
| | | Stress (MPa) | 538.7 | 508.5 | 476.6 | 401.9 | 288 | 534.5 |
| | 100 | Deformation | −168 | −159 | −143 | −118 | −83.5 | −173.14 |
| | | (μm) | | | | | | |
| | | Stress (MPa) | 5387 | 5085 | 4766 | 4019 | 2880 | 5345.2 |
| | 150 | Deformation | −252 | −239 | −214 | −177 | −125 | −259.71 |
| | | (μm) | | | | | | |
| | | Stress (MPa) | 8081 | 7627 | 7149 | 6028 | 4320 | 8017.8 |
| | 200 | Deformation | −336 | −319 | −286 | −236 | −167 | −346.28 |
| | | (μm) | | | | | | |
| | | Stress (MPa) | 10774 | 10169 | 9531 | 8037 | 5760 | 10690.4 |

As shown in Table 1, due to the metallic reticulated structure 2 being disposed on the silicon substrate 1, each of the infrared filter 100 of Examples 1 to 5 has a lower deformation compared to that of the conventional infrared filter of the comparative example under different stress conditions. Furthermore, the thicker the metallic reticulated structure 2 is, the lower the deformation of the infrared filter 100 is. These results indicate that the mechanical strength of the infrared filter 100 can be enhanced by inclusion of the metallic reticulated structure 2 in a manner similar to reinforced concrete having concrete and reinforcing steel bars.

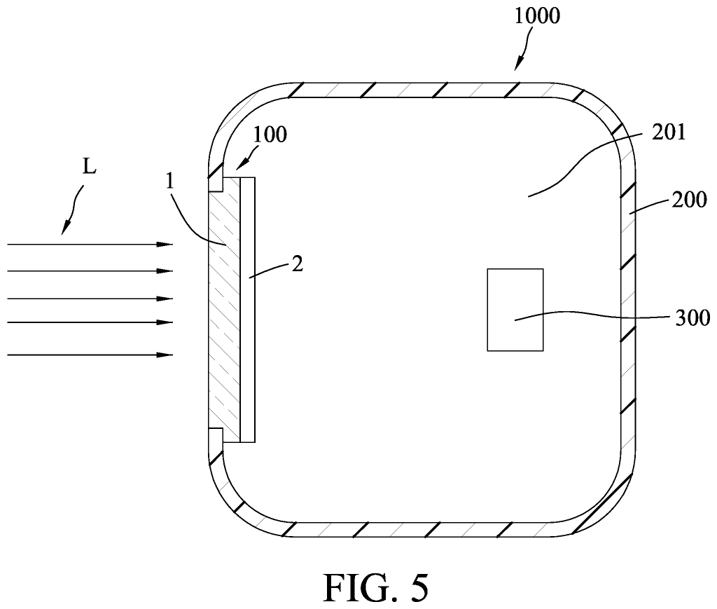

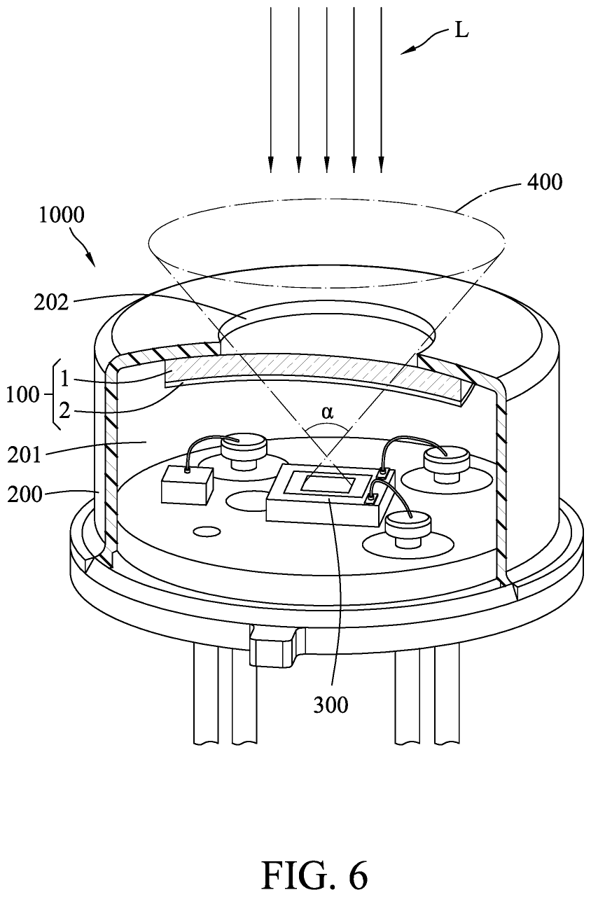

Referring to FIGS. 5 and 6, a thermal infrared sensing device 1000 of the disclosure includes a housing 200 defining a vacuum chamber 201, a thermal infrared image detector 300 disposed within the vacuum chamber 201, and the abovementioned infrared filter 100 coupled to the housing 200 and spaced apart from the thermal infrared image detector 300. The metallic reticulated structure 2 of the infrared filter 100 faces the thermal infrared image detector 300. The infrared filter 100 allows the incident infrared light (L) to transmit therethrough so as to be detected by the thermal infrared image detector 300.

In this embodiment, the housing 200 has an aperture 202 that cooperates with the thermal infrared image detector 300 to define a field of view 400 with an angle (a), and the infrared filter 100 is coupled to the housing 200 in alignment with the aperture 202, as shown in FIG. 6. The incident infrared light (L) within the field of view 400 is detectable by the thermal infrared image detector 300.

In some embodiments, the thermal infrared image detector 300 may include a thermopile chip for receiving radiant energy of the incident infrared light (L) and converting the radiant energy to electrical energy. In some embodiments, the thermopile chip may include a semiconductor substrate (e.g., such as doped or undoped crystalline silicon, germanium, or the like), and a plurality of electronic devices formed thereon.

In some embodiments, the silicon substrate 1 of the infrared filter 100 serves as an optical filter selectively transmit the incident infrared light (L).

Due to the silicon substrate 1 having a thickness of less than 0.5 mm, the silicon substrate 1 has a higher transmittance to the infrared light (L) having a wavelength ranging from 8 μm to 14 μm, i.e., a wave band known as thermal infrared. The silicon substrate 1 having a higher transmittance to the infrared light (L) permits the thermal infrared image detector 300 to have a higher sensitivity. Furthermore, the metallic reticulated structure 2 disposed on the silicon substrate 1 enhances the mechanical strength of the infrared filter 100 and reduces the possibility of breakage or deformation of the silicon substrate 1 having a lower thickness, even if a higher external force is applied thereto. Additionally, compared with the germanium substrate, the silicon substrate 1 used in the infrared filter 100 greatly reduces the production cost of the thermal infrared sensing device 1000. Besides, by using the Czochralski method to fabricate the silicon substrate 1, the production cost of the same can be further reduced.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. An infrared filter, comprising:
a silicon substrate; and
a metallic reticulated structure that is disposed on said silicon substrate and that is formed with a plurality of holes for transmitting an infrared light.

2. The infrared filter as claimed in claim 1, wherein said metallic reticulated structure includes a metallic frame, and a plurality of metallic wires that are connected to said metallic frame and that are interlaced with each other to form said holes.

3. The infrared filter as claimed in claim 1, wherein said silicon substrate has a thickness of less than 0.5 mm.

4. The infrared filter as claimed in claim 1, wherein said metallic reticulated structure is made of titanium.

5. The infrared filter as claimed in claim 1, wherein each of said holes has a dimension selected from a square, a rectangle, a rhombus, a circle, and a hexagon.

6. The infrared filter as claimed in claim 5, wherein said dimension of each of said holes is square and said holes has a length of 50 μm and a width of 50 μm.

7. A thermal infrared sensing device, comprising:
a housing defining a vacuum chamber;
a thermal infrared image detector disposed within said vacuum chamber; and
said infrared filter as claimed in claim 1 coupled to said housing and spaced apart from said thermal infrared image detector, said metallic reticulated structure of said infrared filter facing said thermal infrared image detector,
wherein said infrared filter allows an incident infrared light to transmit therethrough so as to be detected by said thermal infrared image detector.

8. The thermal infrared sensing device as claimed in claim 7, wherein said metallic reticulated structure includes a metallic frame, and a plurality of metallic wires that are connected to said metallic frame and that are interlaced with each other to form said holes.

9. The thermal infrared sensing device as claimed in claim 7, wherein said silicon substrate has a thickness of less than 0.5 mm.

10. The thermal infrared sensing device as claimed in claim 7, wherein said metallic reticulated structure is made of titanium.

11. The thermal infrared sensing device as claimed in claim 7, wherein each of said holes has a dimension selected from a square, a rectangle, a rhombus, a circle, and a hexagon.

12. The thermal infrared sensing device as claimed in claim 11, wherein said dimension of each of said holes is square and said holes has a length of 50 μm and a width of 50 μm.
